(19) United States
(12) Patent Application Publication
(10) Pub. No.: US 2008/0029830 A1
(43) Pub. Date: Feb. 7, 2008

(54) Forming reverse-extension MOS in standard CMOS flow

(75) Inventors: Yung Chih Tsai, Jhudong Town (TW); Chih-Ping Chao, Hsin-Chu (TW); Chih-Sheng Chang, Hsinchu (TW); Michael Yu, Taichung City (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/496,838

(22) Filed: Aug. 1, 2006

(51) Int. Cl. H01L 29/76

(52) U.S. Cl. 257/408

(57) ABSTRACT

A reverse-extension MOS (REMOS) device and a method for forming the same are provided. The REMOS device includes a gate dielectric over a semiconductor substrate, a gate electrode on the gate dielectric, a lightly doped drain/source (LDD) region in the semiconductor substrate and having a portion extending under the gate electrode, a deep source/drain region in the semiconductor substrate, and an embedded region enclosed by a top surface of the semiconductor substrate, the LDD region, and the deep source/drain region. The embedded region is of a first conductivity type, and the LDD region and the deep source/drain region are of a second conductivity type opposite the first conductivity type. The embedded region and the LDD region are preferably formed simultaneously with the formation of a LDD region and a pocket region of an additional MOS device, respectively.

### TECHNICAL FIELD

This invention relates generally to semiconductor devices, and more particularly to structures and manufacturing methods of MOS devices having reverse extensions.

### BACKGROUND

Complementary metal-oxide-semiconductor (CMOS) devices are key components of modem integrated circuits. Different designs of CMOS devices have been provided to achieve performance and/or reliability gains based on the requirements of applications.

One of the commonly used CMOS devices is shown in FIG. 1. A gate dielectric 4 and a gate electrode 6 are formed on a P-well. N-type lightly doped drain/source (LDD) regions 12 are formed close to a channel region in the P-well, which is under gate dielectric 4. P-type pocket regions 14 are formed in regions adjacent LDD regions 12, and preferably under the LDD regions 12. N-type deep source/drain regions 10 adjoin respective LDD regions 12. The MOS device is commonly referred to as an NMOS device.

A MOS device having the above-discussed structure may suffer two problems. A first problem is that the formation of the pocket regions 14, which have an opposite conductivity type from LDD regions 12 and deep source/drain regions 10, significantly affects the matching between characteristics of the MOS devices. Accordingly, if high matching between MOS devices is preferred, no pocket regions 14 will be formed. A second problem is that hot carriers may be generated in the P-well when the MOS device is turned on. Since hot carriers have high energies and are typically transported adjacent the interface between the gate dielectric 4 and the P-well, the gate dielectric 4 may be damaged.

Accordingly, what is needed in the art is a semiconductor device that may solve the above-discussed problems while at the same time using existing formation processes without introducing more process steps.

### SUMMARY OF THE INVENTION

In accordance with one aspect of the present invention, a reverse-extension MOS (REMOS) device includes a gate dielectric over a semiconductor substrate, a gate electrode on the gate dielectric, a lightly doped drain/source (LDD) region in the semiconductor substrate and having a portion extending under the gate electrode, a deep source/drain region in the semiconductor substrate, and an embedded region enclosed by a top surface of the semiconductor substrate, the LDD region, and the deep source/drain region. The embedded region is of a first conductivity type, and the LDD region and the deep source/drain region are of a second conductivity type opposite the first conductivity type. The LDD region, the embedded region, and the deep source/drain region are formed in a sub-region of the substrate, wherein the sub-region is of the first conductivity type.

In accordance with another aspect of the present invention, a reverse-extension MOS (REMOS) device includes a gate dielectric over a semiconductor substrate, a gate electrode on the gate dielectric, an embedded region of a first conductivity type in the semiconductor substrate and substantially aligned with an edge of the gate electrode, a lightly doped drain/source (LDD) region of a second conductivity type opposite the first conductivity type in the semiconductor substrate, a gate spacer on a sidewall of the gate electrode, and a deep source/drain region of the second conductivity type in the semiconductor substrate wherein the deep source/drain region is substantially aligned with an edge of the gate spacer.

In accordance with yet another aspect of the present invention, a semiconductor structure includes a semiconductor substrate comprising a first region of a first conductivity type and a second region of a second conductivity type opposite the first conductivity type, and a REMOS device on the first region and an additional MOS device on the second region. The REMOS device includes a gate dielectric over the semiconductor substrate, a gate electrode on the gate dielectric, a lightly doped drain/source (LDD) region in the semiconductor substrate wherein the LDD region has a portion extending under the gate electrode, and an embedded region enclosed by a top surface of the semiconductor substrate, the LDD region, and the deep source/drain region. The embedded region is of the first conductivity type. The LDD region and the deep source/drain region are of the second conductivity type. The additional MOS device includes an additional gate dielectric over the semiconductor substrate, an additional gate electrode on the additional gate dielectric, an additional lightly doped drain/source (LDD) region in the semiconductor substrate, an additional pocket region in the semiconductor substrate, and an additional deep source/drain region of the first conductivity type in the semiconductor substrate. Preferably, the embedded region and the additional LDD region comprise a same impurity and have a substantially same thickness, and the LDD region and the additional pocket region comprise a same impurity and have a substantially same thickness.

In accordance with yet another aspect of the present invention, a method of forming a REMOS device includes providing a semiconductor substrate comprising a region of a first conductivity type, forming a gate stack over the semiconductor substrate, implanting a first impurity of the first conductivity type to form an embedded region in the semiconductor substrate, and implanting a second impurity of a second conductivity type opposite the first conductivity type to form an LDD region. The method further includes forming a deep source/drain region of the second conductivity type in the semiconductor substrate. Preferably, the embedded region is enclosed by a top surface of the semiconductor substrate, the LDD region, and the deep source/drain region.

In accordance with yet another aspect of the present invention, a method of forming a semiconductor structure includes providing a semiconductor substrate comprising a first region and a second region wherein the first region is of a first conductivity type and the second region is of a second conductivity type opposite the first conductivity type, forming a first gate stack over the semiconductor substrate in the first region and a second gate stack over the semiconductor substrate in the second region, implanting a first impurity of the first conductivity type to simultaneously form an embedded region in the first region and a second LDD region in the second region, and implanting a second impurity of the second conductivity type to simultaneously form a first LDD region in the first region and a pocket region in the second region. The method further includes forming a first deep source/drain region in the semiconductor substrate and forming a second deep source/drain region in the semiconductor substrate.

The advantageous features of the REMOS devices include a high degree of matching between characteristics of devices and improved reliability.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional MOS device with lightly doped drain/source regions and pocket regions;

FIGS. 2 through 7 are cross-sectional views of intermediate stages in the manufacture of a reverse-extension MOS (REMOS) device;

FIG. 8 illustrates an operational state of a RE-NMOS device;

FIG. 9 illustrates a symmetric RE-PMOS device;

FIG. 10 illustrates a symmetric native RE-NMOS device;

FIGS. 11 through 13 are asymmetric REMOS devices;

FIGS. 14 through 17 illustrate asymmetric high-voltage REMOS devices;

FIGS. 18 through 20 illustrate asymmetric REMOS devices, wherein an embedded region and a LDD region are formed on one of the source/drain sides, and a LDD region and a pocket region are formed on the other side; and

FIGS. 21 through 23 illustrate asymmetric REMOS devices, wherein an embedded region and a LDD region are formed on one of the source/drain sides, and an I/O LDD region is formed on the other side.

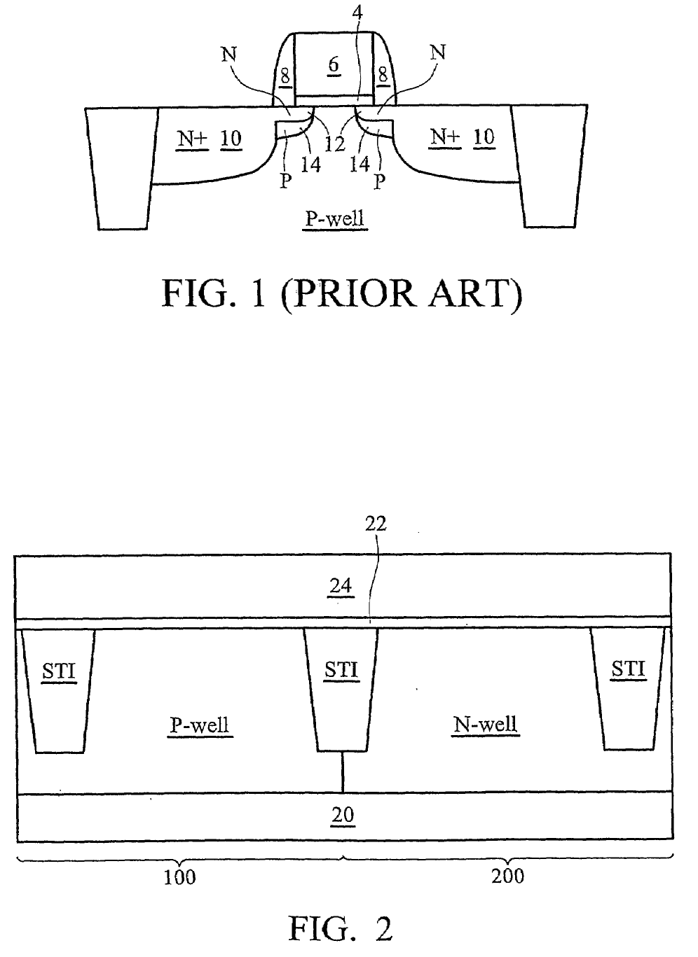

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Novel MOS devices referred to as reverse-extension metal-oxide-semiconductor (REMOS) devices and a method of forming the same are provided. The cross-sectional views of intermediate stages in the manufacturing of a preferred embodiment of the present invention are illustrated. The variations of the preferred embodiments are then discussed. Throughout the various views and illustrative embodiments of the present invention, like reference numbers are used to designate like elements.

FIG. 2 illustrates a substrate 20, which includes a first region 100 and a second region 200 isolated by shallow trench isolation (STI) regions. Substrate 20 preferably comprises bulk silicon, although other commonly used structures and materials such as silicon-on-insulator (SOI) and silicon alloys may be used. First region 110 comprises a P-well for forming an n-type REMOS device, while second region 200 comprises an N-well for forming a conventional p-type MOS device.

A gate dielectric layer 22 is formed on the substrate 20. Depending on the type of the MOS devices to be formed, gate dielectric layer 22 may be formed of silicon oxides or high dielectric-constant (k value) materials. For example, silicon oxide is preferably used for the formation of I/O MOS devices, while high-k dielectric materials are preferably used for core circuits. The preferred methods for forming the gate dielectric layer 22 include chemical vapor deposition (CVD) techniques such as low temperature CVD (LTCVD), low pressure CVD (LPCVD), rapid thermal CVD (RTCVD), plasma enhanced CVD (PECVD), and other commonly used methods. A gate electrode layer 24 is formed on the gate dielectric layer 22. The gate electrode layer 24 preferably comprises polysilicon, metals, metal alloys, metal silicides, and the like.

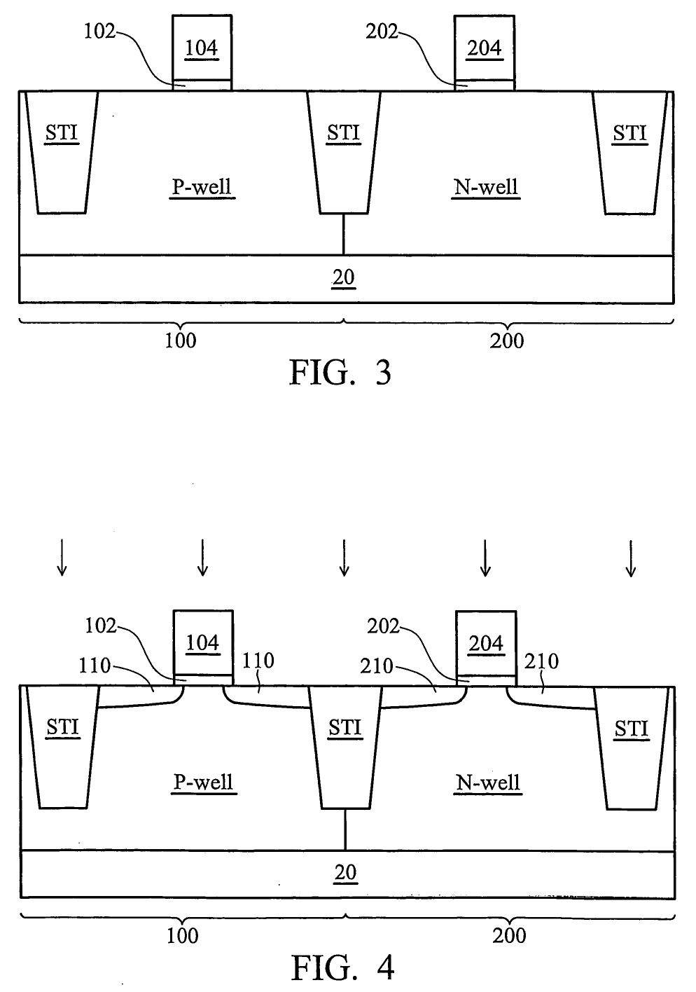

FIG. 3 illustrates the formation of gate stacks. The gate dielectric layer 22 and gate electrode layer 24 are patterned, forming gate stacks in regions 100 and 200. The remaining portions of gate electrode layer 24 and gate dielectric layer 22 form gate electrodes 104 and 204 and gate dielectrics 102 and 202, respectively.

Referring to FIG. 4, an implantation is performed to introduce p-type impurities, forming embedded regions 110 and lightly doped drain/source (LDD) regions 210 in regions 100 and 200, respectively. In the preferred embodiment, the implantation is substantially vertical, thus embedded regions 110 and LDD regions 210 are substantially aligned with the edges of gate electrodes 104 and 204, respectively. As is known in the art, subsequent annealing processes will cause the implanted regions, including embedded regions 110 and LDD regions 210, to diffuse. Thus the embedded regions 110 and LDD regions 210 may extend slightly under the respective gate electrodes 104 and 204.

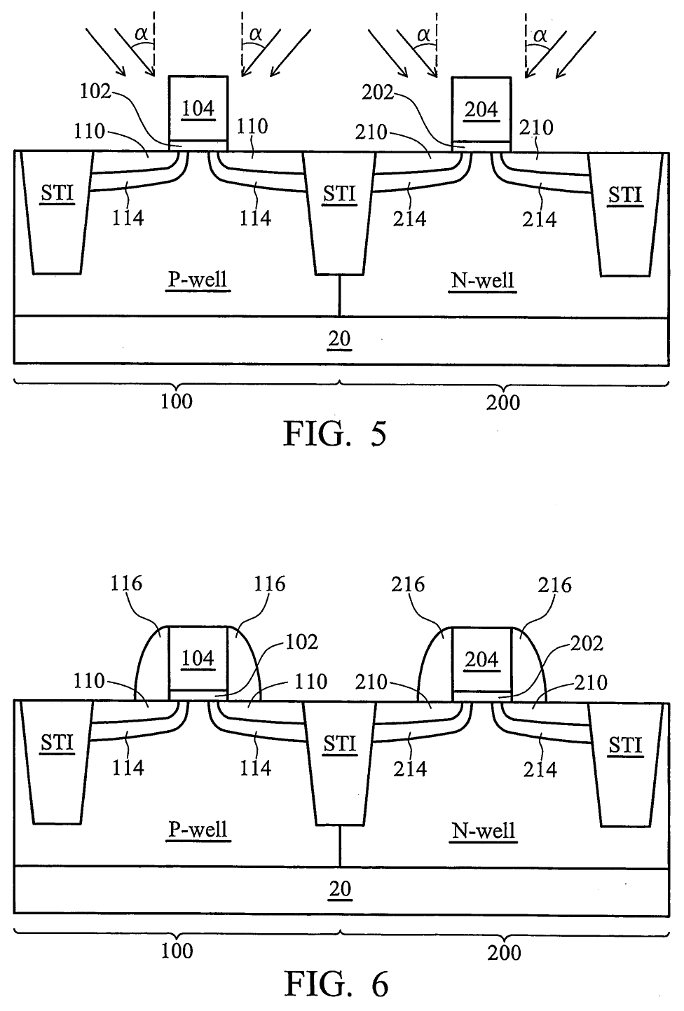

FIG. 5 illustrates the formation of LDD regions 114 and pocket regions 214 in regions 100 and 200, respectively, preferably by implanting an n-type impurity. In the preferred embodiment, the implantation is performed in two steps, each tilting at an angle α, respectively. With the tilt implants, the respective LDD regions 114 and pocket regions 214 extend further under the respective gate dielectrics 102 and 202. After the subsequent annealing process, LDD regions 114 and pocket regions 214 preferably enclose the respective embedded regions 110 and LDD regions 210 from the bottom and the channel side.

Gate spacers 116 and 216 are then formed, as shown in FIG. 6. As is known in the art, the gate spacers 116 and 216 may be formed by forming one or more spacer layers (not shown) and etching the horizontal portions of the spacer layer(s). In the preferred embodiment, the spacer layer includes a nitride sub-layer on a liner oxide sub-layer. The preferred spacer deposition methods include PECVD, LPCVD, sub-atmospheric chemical vapor deposition (SACVD), and the like.

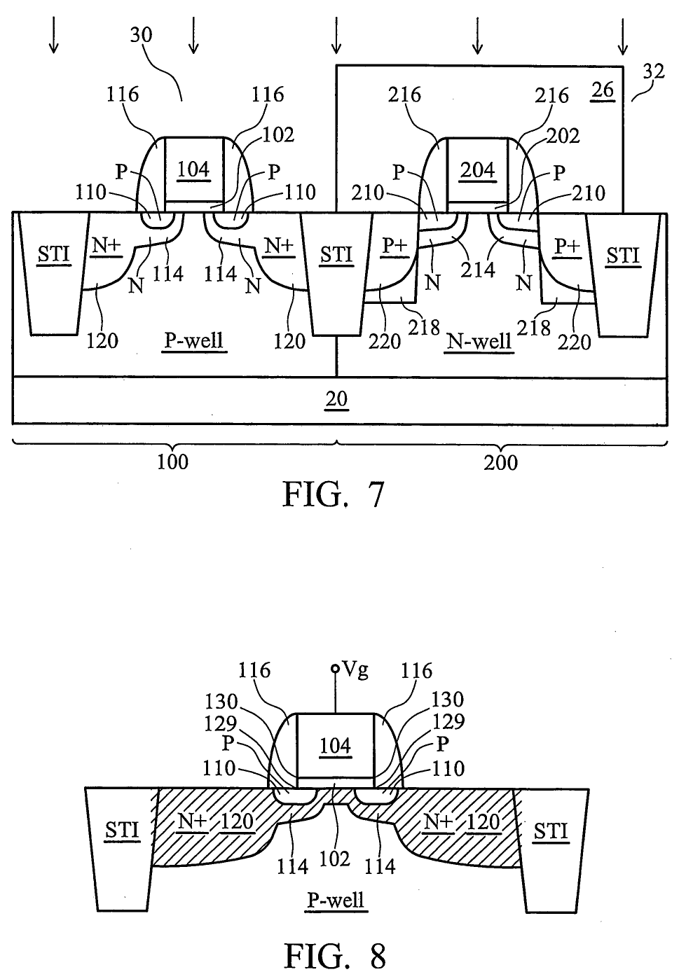

SiGe stressors 218 may be formed for the PMOS device in region 200, as shown in FIG. 7. Preferably, the formation steps include forming recesses in region 200 using gate spacers 216 and gate electrode 204 as a mask, and epitaxially growing SiGe in the recesses. The SiGe stressors 218 apply a compressive stress to the channel region of the respective PMOS devices, and thus the performance of the respective PMOS devices is enhanced.

FIG. 7 also illustrates the formation of deep source/drain regions 120 and 220. To form deep source/drain regions 120, region 200 is masked by a photo resist 26, and an n-type impurity is implanted. Photo resist 26 is then removed. Similarly, to form deep source/drain regions 220, a photo resist (not shown) is formed to mask region 100, and a p-type impurity is implanted. The resulting deep source/drain regions 120 and 220 are substantially aligned with the edges of the spacers 116 and 216, respectively.

To finish the formation of MOS devices, silicide regions (not shown) are formed on exposed surfaces of the source/drain regions and the gate electrodes of the MOS devices, followed by the formation of an etch stop layer (ESL, not shown) and an inter-layer dielectric (ILD, not shown). The details for forming the silicide regions, the ESL and the ILD are well known in the art, thus are not repeated herein.

In the previously discussed embodiment, an n-type MOS device 30 is formed in region 100 and a PMOS device 32 is formed in region 200. FIG. 8 illustrates the MOS device 30 in an “on” state. The embedded regions 110 are referred to as reverse extensions as they are of an opposite type as the respective deep source/drain regions 120. MOS device 30 is hence referred to as a reverse-extension MOS (REMOS). Neutralized by the n-type impurity in deep source/drain regions 120, which have a much higher concentration, the embedded regions 110 are reduced to regions substantially underlying the gate dielectric 102 and gate spacers 116. As is shown in FIG. 8, when a gate voltage Vg is applied on the gate electrode 104 and causes the REMOS 30 to be turned on, an n-type conducting path exists between the source and drain regions. The conducting path is shaded for a clear view.

Note that the embedded regions 110 are of p-type, thus act as isolation regions for carriers. If hot carriers are generated, hot carriers are kept away from bottom corner regions 129 of the gate dielectric 102 by the embedded regions 110, thus damage to the gate dielectric 102 is reduced. Particularly, in gate dielectric 102 adjacent the corners 130, electric fields are typically strong. The formation of the embedded regions 110 increases the distance between the gate drain/source region and the bottom corners 130 of the gate electrode 104. Therefore, the electric field in gate dielectric 102 adjacent corners 130 is reduced. The likelihood of discharging at the bottom corners 130 is also reduced.

The REMOS devices have good matching in characteristics between devices. One of the reasons is that in typical MOS devices, there are pocket regions having an opposite type from the respective source/drain regions, and the pocket regions significantly affect matching in characteristics between devices. In the preferred embodiment of the present invention, the pocket regions in typical MOS devices are converted into LDD regions having a same type as the source/drain regions. Although a top region of the gate electrode 104 has opposite-type doping, which is introduced when the embedded regions 110 are formed, since the oppositely doped region is shallow and is consumed by the subsequent silicide process, the adverse effects are minimal.

An advantageous feature of the preferred embodiment of the present invention is that embedded regions 110 and LDD regions 210 are formed using a same mask and in a same process step. Similarly, LDD regions 114 and pocket regions 214 are formed using a same mask and in a same process step. Therefore, no additional cost is introduced for forming REMOS devices. Furthermore, no additional cost is introduced for forming REMOS devices and traditional MOS devices on a same chip. In alternative embodiments, LDD regions 110 and 210 can be formed in different steps using different masks. An advantageous feature of these embodiments is that the depth and concentrations of embedded regions 110 and LDD regions 114 can be separately adjusted for optimum performance. Similarly, LDD regions 114 and pocket regions 214 can be formed separately.

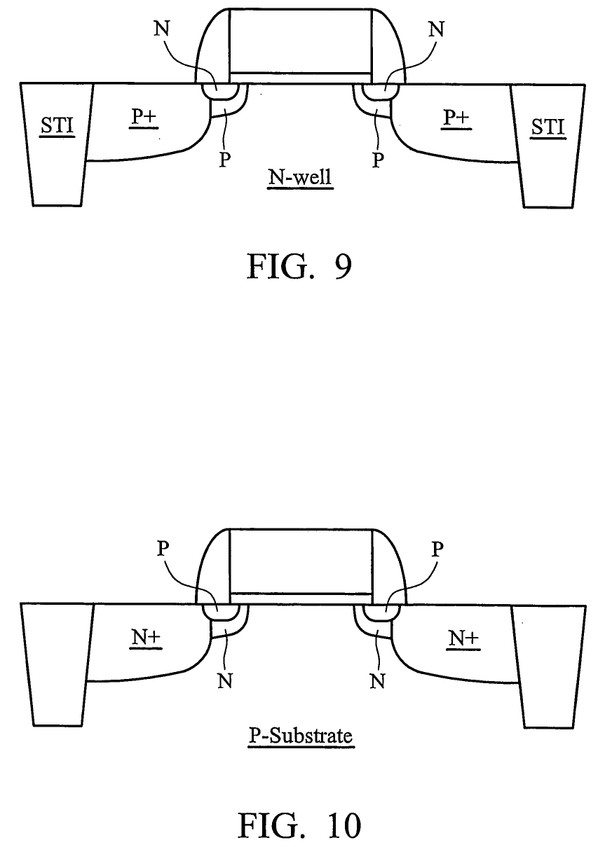

Although the preferred embodiments provide a method of forming a RE-NMOS device, one skilled in the art will realize that the teaching provided is readily available for the formation of RE-PMOS devices, with the types of the respective well regions, embedded regions, LDD regions and deep source/drain regions inverted. An exemplary embodiment of a RE-PMOS is shown in FIG. 9, wherein the impurity types are marked. In further embodiments, as shown in FIG. 10, a native RE-NMOS is formed in a p-type substrate instead of a P-well region. Additionally, the previously discussed embodiments may be applied to the formation of core devices and I/O devices.

It should be appreciated that different applications may require different preferences for doping concentrations and depths of embedded regions 110 and LDD regions 210, as well as LDD regions 114 and pocket regions 214. These preferences are preferably balanced for optimum overall performance of the integrated circuits. In an exemplary embodiment, the concentrations of the embedded regions 110 and LDD regions 210 are in a same order, although conventional LDD regions may have a concentration one order higher than the concentration of pocket regions.

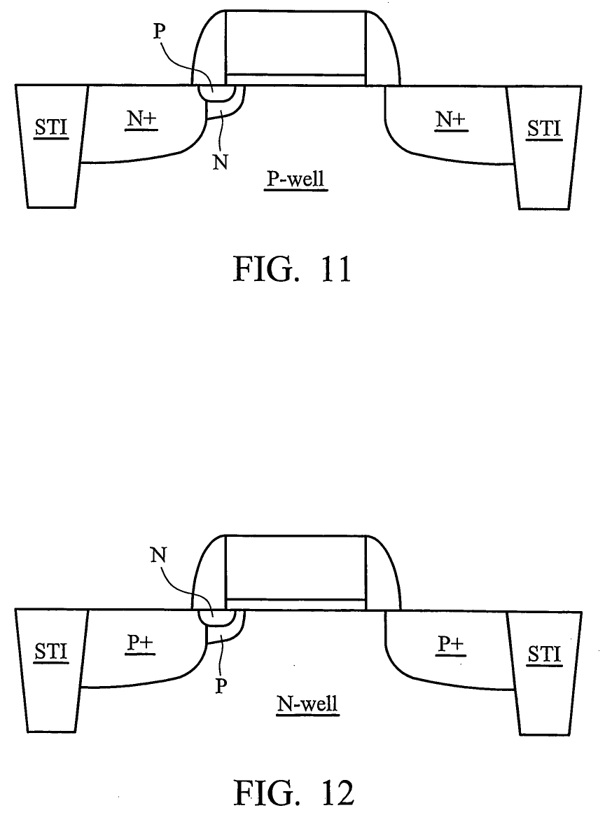

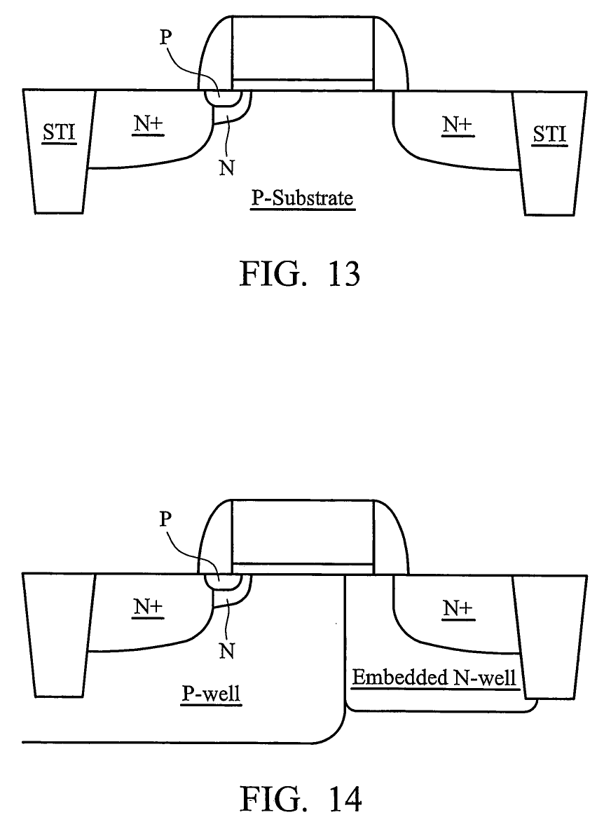

REMOS devices shown in FIGS. 8 through 10 are symmetric REMOS devices in the sense that the source region and the drain region have similar structures. FIGS. 11, 12 and 13 illustrate an asymmetric RE-NMOS device, an asymmetric RE-PMOS device and an asymmetric native RE-NMOS device, respectively. For each of the asymmetric REMOS devices, the embedded regions and the LDD regions are formed only on one of the source or drain sides, preferably the source side. These asymmetric REMOS devices can be used as electro-static discharge (ESD) devices. Preferably, no LDD regions are formed on the drain sides.

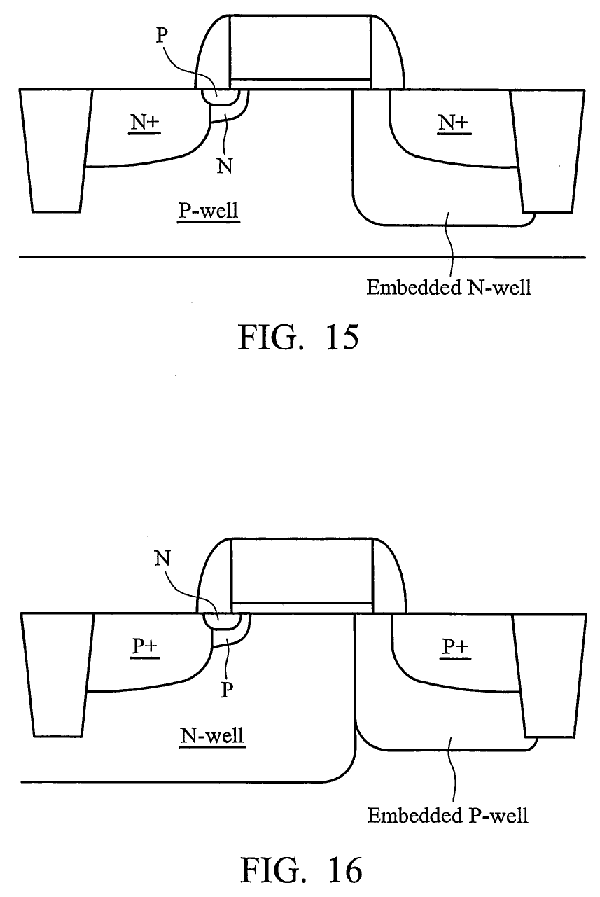

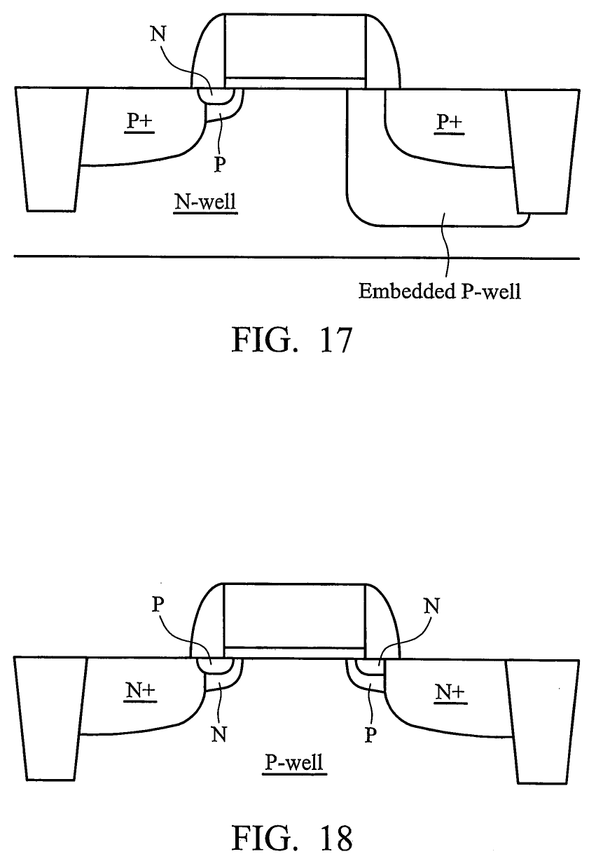

FIGS. 14 through 17 are different versions of asymmetric high-voltage REMOS devices, wherein devices in FIGS. 14 and 15 are RE-NMOS devices and devices in FIGS. 16 and 17 are RE-PMOS devices. In each of the REMOS devices, an embedded well region, which has a low impurity concentration in order to sustain high voltages, is formed on the drain side. Preferably, no embedded regions or LDD regions are formed on the drain side. The reason is that the embedded regions and LDD regions typically have concentrations one or more orders higher than the concentrations in the embedded well regions, thus the formation of embedded regions and LDD regions on the drain side compromises the ability of the REMOS devices to sustain high voltages.

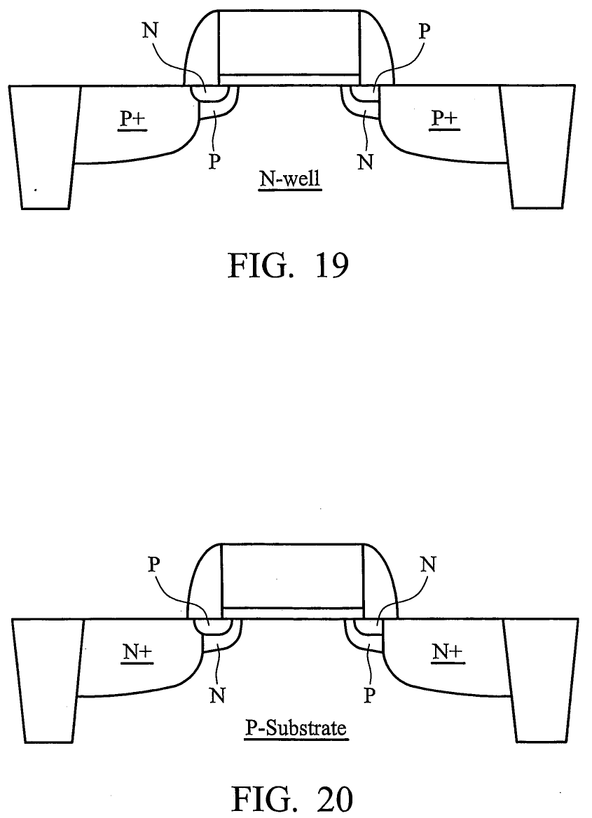

REMOS devices in FIGS. 18 through 20 are also asymmetric MOS devices, wherein the embedded regions and the LDD regions are formed on one of the source/drain sides, and conventional LDD regions and pocket regions are formed on the other side.

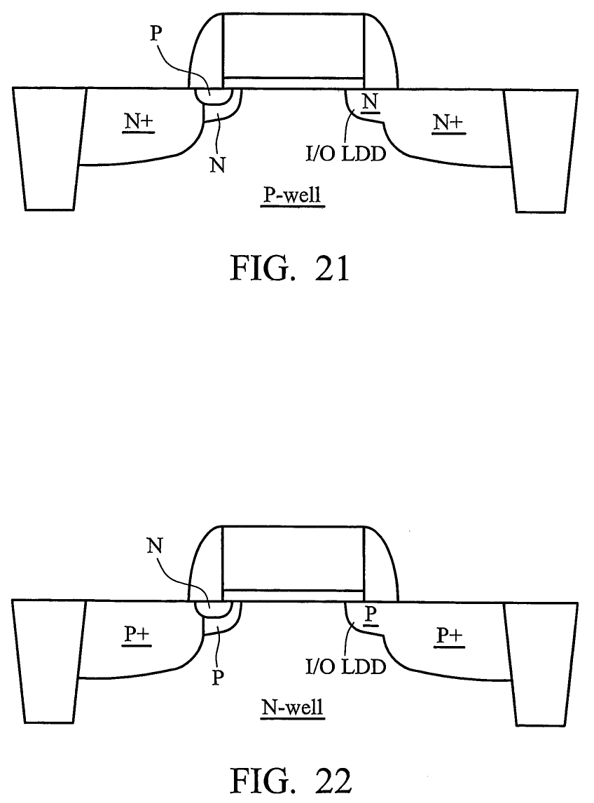

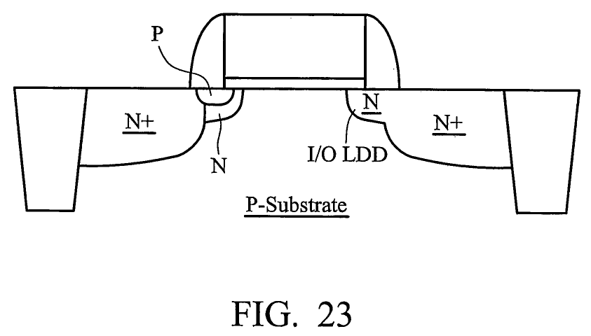

FIGS. 21 through 23 are asymmetric structures with core embedded regions and LDD regions on one side and I/O LDD regions on the other side. Preferably, the I/O LDD regions are deeper and have lower concentrations than the core embedded LDD regions.

It is appreciated that more REMOS device embodiments exist. Regardless of whether the REMOS devices are symmetric or asymmetric, and regardless of whether these REMOS devices are formed on a same chip as conventional MOS devices, only the layout of the respective photo masks needs to be changed, and no additional masks are needed.

The preferred embodiments of the present invention have several advantageous features. As previously discussed, REMOS devices have improved reliability since the gate dielectrics are protected by the embedded regions. The formation of different variations of the present invention does not need additional photo masks. The REMOS devices have good matching of characteristics between devices.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor structure comprising:
a semiconductor substrate;
a gate dielectric over the semiconductor substrate;
a gate electrode on the gate dielectric;
a lightly doped drain/source (LDD) region in the semiconductor substrate, the LDD region having a portion extending under the gate electrode;
a deep source/drain region in the semiconductor substrate; and
an embedded region enclosed by a top surface of the semiconductor substrate, the LDD region, and the deep source/drain region, wherein the embedded region is of a first conductivity type, and the LDD region and the deep source/drain region are of a second conductivity type opposite the first conductivity type, and wherein the LDD region, the embedded region, and the deep source/drain region are formed in a sub-region of the semiconductor substrate, the sub-region being of the first conductivity type.

2. The semiconductor structure of claim 1, wherein the sub-region is a well region.

3. The semiconductor structure of claim 1, wherein the embedded region and the LDD region are formed only on one of the source and drain sides.

4. The semiconductor structure of claim 2, wherein the embedded region and the LDD region are formed only on the source side.

5. The semiconductor structure of claim 1, wherein the first conductivity type is n-type and the second conductivity type is p-type.

6. The semiconductor structure of claim 1, wherein the first conductivity type is p-type and the second conductivity type is n-type.

7. A MOS device comprising:
a semiconductor substrate;
a gate dielectric over the semiconductor substrate;
a gate electrode on the gate dielectric;
an embedded region of a first conductivity type in the semiconductor substrate and substantially aligned with an edge of the gate electrode;
a lightly doped drain/source (LDD) region of a second conductivity type opposite the first conductivity type in the semiconductor substrate, the LDD region having a portion adjacent a bottom of the embedded region;
a gate spacer on a sidewall of the gate electrode; and
a deep source/drain region of the second conductivity type in the semiconductor substrate, the deep source/drain region being substantially aligned with an edge of the gate spacer.

8. The MOS device of claim 7 further comprising a well region of the first conductivity type, wherein the embedded region, the LDD region, and the deep source/drain region are formed in the well region.

9. The MOS device of claim 7 being a native MOS device, wherein the semiconductor substrate is of the first conductivity type, and wherein the embedded region, the LDD region and the deep source/drain region are formed directly in the semiconductor substrate.

10. The MOS device of claim 7, wherein the embedded region and the LDD region are formed only on one of the source and drain sides.

11. The MOS device of claim 10, wherein the embedded region and the LDD region are formed only on the source side.

12. A semiconductor structure comprising:
a semiconductor substrate comprising a first region of a first conductivity type and a second region of a second conductivity type opposite the first conductivity type;
a reverse-extension MOS (REMOS) device on the first region comprising:
a gate dielectric over the semiconductor substrate;
a gate electrode on the gate dielectric;
a lightly doped drain/source (LDD) region in the semiconductor substrate, the LDD region having a portion extending into a region under the gate electrode;
a deep source/drain region in the semiconductor substrate; and
an embedded region enclosed by a top surface of the semiconductor substrate, the LDD region, and the deep source/drain region, wherein the embedded region is of the first conductivity type, and the LDD region and the deep source/drain region are of the second conductivity type;
an additional MOS device on the second region comprising:
an additional gate dielectric over the semiconductor substrate;
an additional gate electrode on the additional gate dielectric;
an additional lightly doped drain/source (LDD) region in the semiconductor substrate;
an additional pocket region in the semiconductor substrate, the additional pocket region having a portion adjacent a bottom portion of the additional LDD region; and
an additional deep source/drain region of the first conductivity type in the semiconductor substrate; and
wherein the embedded region and the additional LDD region comprise a same impurity and have a substantially same thickness, and wherein the LDD region and the additional pocket region comprise a same impurity and have a substantially same thickness.

13. The semiconductor structure of claim 12, wherein the first conductivity type is p-type and the second conductivity type is n-type.

14. The semiconductor structure of claim 12, wherein the first conductivity type is n-type and the second conductivity type is p-type.

15. A method for forming a semiconductor structure, the method comprising:
providing a semiconductor substrate comprising a region of a first conductivity type;
forming a gate stack over the region;
implanting a first impurity of the first conductivity type using the gate stack as a mask to form an embedded region in the semiconductor substrate;
implanting a second impurity of a second conductivity type to form an LDD region; and
forming a deep source/drain region of the second conductivity type in the semiconductor substrate, wherein the embedded region is enclosed by a top surface of the semiconductor substrate, the LDD region, and the deep source/drain region.

16. The method of claim 15 further comprising forming a well region of the first conductivity type over the semiconductor substrate, wherein the embedded region, the LDD region, and the deep source/drain region are formed in the well region.

17. The method of claim 15, wherein the first conductivity type is p-type and the second conductivity type is n-type.

18. The method of claim 15, wherein the first conductivity type is n-type and the second conductivity type is p-type.

19. The method of claim 15, wherein the first impurity is substantially vertically implanted and the second impurity is implanted at a tilt angle.

20. A method for forming a semiconductor structure, the method comprising:
providing a semiconductor substrate comprising a first region and a second region, wherein the first region is of a first conductivity type and the second region is of a second conductivity type opposite the first conductivity type;
forming a first gate stack over the semiconductor substrate in the first region, and a second gate stack over the semiconductor substrate in the second region;
implanting a first impurity of the first conductivity type to simultaneously form an embedded region in the first region and a second LDD region in the second region;
implanting a second impurity of the second conductivity type to simultaneously form a first LDD region in the first region and a pocket region in the second region;
forming a first deep source/drain region of the second conductivity type in the semiconductor substrate; and
forming a second deep source/drain region of the first conductivity type in the semiconductor substrate.

21. The method of claim 20 wherein the first region and the second region are well regions.

22. The method of claim 20, wherein the first conductivity type is p-type and the second conductivity type is n-type.

23. The method of claim 20, wherein the first conductivity type is n-type and the second conductivity type is p-type.

24. The method of claim 20, wherein the first impurity is substantially vertically implanted and the second impurity is implanted at a tilt angle.
